(19) United States
(12) Patent Application Publication
(10) Pub. No.: US 2026/0059675 A1
(43) Pub. Date: Feb. 26, 2026

(54) FOLDABLE DISPLAY DEVICE AND ELECTRONIC DEVICE INCLUDING THE SAME

(71) Applicants: Samsung Display Co., Ltd., YONGIN-SI (KR); Industry-Academic Cooperation Foundation, Yonsei University, Seoul (KR)

(72) Inventors: TAEWOONG KIM, Yongin-si (KR); Jong Hyun AHN, Seoul (KR); Beom Jin KIM, Seoul (KR); Seok Min YUN, Seoul (KR)

(21) Appl. No.: 19/295,775

(22) Filed: Aug. 11, 2025

(30) Foreign Application Priority Data
Aug. 20, 2024 (KR) 10-2024-0111604

(51) Int. Cl. H05K 5/02

(52) U.S. Cl. CPC H05K 5/0217

(57) ABSTRACT

A foldable display device including a display panel including a folding area and a non-folding area adjacent to at least one side of the folding area. A support layer is disposed on the display panel. The support layer includes a pattern portion overlapping the folding area. The pattern portion includes a first area having a first modulus, and a second area disposed on at least one side of the first area and having a second modulus different from the first modulus.

### CROSS-REFERENCE TO RELATED APPLICATION

This application claims priority under 35 U.S.C. § 119 to Korean Patent Application No. 10-2024-0111604, filed on Aug. 20, 2024, in the Korean Intellectual Property Office, the present disclosure of which is incorporated by reference in its entirety herein.

### 1. TECHNICAL FIELD

Embodiments of the present disclosure relate to a light-emitting display device, and more particularly, to a foldable display device capable of state switching between a folded state and an unfolded state.

### 2. DISCUSSION OF RELATED ART

Display devices refer to devices that display an image. Display devices have various types of display panels, such as organic light-emitting display panels, liquid crystal display panels, etc.

Mobile electronic devices include display devices to provide images to users. The screen size on mobile electronic devices are increasing while the volume or thickness of the device is the same or decreasing. Additionally, foldable display devices or bendable display devices having a foldable or unfoldable structure are becoming increasingly popular to provide a larger screen when they are in an unfolded state.

The foldable display devices may require increased flexibility to facilitate folding and unfolding, and thus, the foldable display devices are relatively vulnerable to external impact. Additionally, when the foldable display device is folded, a surface quality of the display device may degrade depending on an internal configuration of the display device.

### SUMMARY

Embodiments of the present disclosure provide a foldable display device that prevents deformation from occurring due to stress and has an increased quality.

Additional aspects will be set forth in part in the description which follows and, in part, will be apparent from the description, or may be learned by practice of the presented embodiments of the present disclosure.

According to an embodiment of the present disclosure, a foldable display device including a display panel including a folding area and a non-folding area adjacent to at least one side of the folding area. A support layer is disposed on the display panel. The support layer includes a pattern portion overlapping the folding area. The pattern portion includes a first area having a first modulus, and a second area disposed on at least one side of the first area and having a second modulus different from the first modulus.

In an embodiment of the present disclosure, the first modulus may be less than the second modulus.

In an embodiment of the present disclosure, the first modulus may be in a range of about 10 MPa to about 300 MPa, and the second modulus may be in a range of about 300 MPa to about 1 GPa.

In an embodiment of the present disclosure, a width of the second area may be equal to a width of the first area.

In an embodiment of the present disclosure, each of the first area and the second area may have a negative Poisson's ratio.

In an embodiment of the present disclosure, the first area may include a first pattern defining a plurality of first unit cells, the second area may include a second pattern defining a plurality of second unit cells, and each of the plurality of first unit cells and the plurality of second unit cells may have a same shape as each other in a plan view.

In an embodiment of the present disclosure, the first pattern and the second pattern may have different line widths from each other.

In an embodiment of the present disclosure, each first unit cell of the plurality of first unit cells may have a size greater than a size of each second unit cell of the plurality of second unit cells.

In an embodiment of the present disclosure, the first pattern and the second pattern may be connected to each other.

In an embodiment of the present disclosure, the pattern portion may further include an intermediate area disposed between the first area and the second area, and the intermediate area may have a positive Poisson's ratio.

In an embodiment of the present disclosure, the first pattern or the second pattern may have at least one of stainless steel, copper, aluminum, and high-density polyethylene (HDPE).

In an embodiment of the present disclosure, the pattern portion may further include a filling member filling openings of the first pattern and the second pattern.

In an embodiment of the present disclosure, the foldable display device may further include an adhesive layer disposed between the display panel and the support layer. The adhesive layer coupling the display panel to the pattern portion.

In an embodiment of the present disclosure, the pattern portion may further include a third area disposed adjacent to the second area and having a third modulus.

In an embodiment of the present disclosure, the first modulus, the second modulus, and the third modulus may have respective sizes that gradually change.

In an embodiment of the present disclosure, a modulus of the pattern portion may decrease toward a center of the pattern portion.

In an embodiment of the present disclosure, a thickness of the support layer may be in a range of about 50 μm to about 100 μm.

According to an embodiment of the present disclosure, a foldable display device includes a display panel and a support layer disposed on the display panel. The support layer includes a first area disposed adjacent to a folding axis of the display panel and a second area arranged on at least one side of the first area, and the first area and the second area have different patterns from each other.

In an embodiment of the present disclosure, a first pattern of the first area may have a line width that is different from a line width of a second pattern of the second area.

In an embodiment of the present disclosure, the first pattern and the second pattern may form unit cells having a same shape as each other in a plan view and sizes that are different from each other in the plan view.

Other aspects, features, advantages, and advantages other than those described above will become apparent from the following figures, claims, and the detailed description of the present disclosure.

### BRIEF DESCRIPTION OF THE DRAWINGS

The above and other aspects, features, and advantages of certain non-limiting embodiments of the present disclosure will be more apparent from the following description taken in conjunction with the accompanying drawings, in which:

FIG. 1 is a perspective view showing an unfolded state of a foldable display device according to an embodiment of the present disclosure;

FIG. 2 is a perspective view showing a folding state of a foldable display device according to an embodiment of the present disclosure;

FIG. 3 is a cross-sectional view of a non-folding state of a foldable display device according to an embodiment of the present disclosure;

FIG. 4 is a cross-sectional view of an in-folding state of a foldable display device according to an embodiment of the present disclosure;

FIG. 5 is a plan view of a support layer according to an embodiment of the present disclosure;

FIG. 6 is a view for describing a pattern formed in a pattern portion of a support layer according to an embodiment of the present disclosure;

FIG. 7 is a plan view of a pattern portion according to an embodiment of the present disclosure;

FIG. 8 is an enlarged plan view of a portion E of FIG. 7 according to an embodiment of the present disclosure;

FIG. 9 is a plan view showing a pattern portion of a foldable display device according to a comparative example;

FIG. 10 is a graph showing bending occurring in foldable display devices according to a first comparative example and a second comparative example and a foldable display device according to an embodiment of the present disclosure;

FIG. 11 is a plan view of a pattern portion of a support layer according to an embodiment of the present disclosure; and

FIG. 12 is a plan view of a pattern portion of a support layer according to an embodiment of the present disclosure.

FIG. 13 is a diagram illustrating an electronic device according to an embodiment of the present disclosure.

### DETAILED DESCRIPTION OF EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, non-limiting embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The present disclosure may have various modifications thereto and various embodiments, and thus non-limiting embodiments will be illustrated in the drawings and described in detail in a detailed description. Effects and features of the present disclosure, and methods for achieving them will become clear with reference to embodiments described later in detail together with the drawings. However, the present disclosure is not limited to the described embodiments and may be implemented in various forms.

In the following embodiments, the terms such as first, second, etc., have been used to distinguish one component from other components, rather than limiting.

In the following embodiments, singular forms include plural forms unless apparently indicated otherwise contextually.

In the following embodiments, the terms “include”, “have”, or the like, are intended to mean that there are features, or components, described herein, but do not preclude the possibility of adding one or more other features or components.

In the following embodiments, when a portion, such as a film, a region, a component, etc., is present on or above another portion, this case may include not only a case where it is directly on the other portion, but also a case where another film, region, component, etc., is arranged between the portion and the other portion.

In the examples below, terms such as connect or combine do not necessarily imply a direct and/or fixed connection or combination of two members, unless the context clearly indicates otherwise, and do not exclude the presence of another member between the two members.

In the drawings, the size of components may be exaggerated or reduced for convenience of description. For example, since the size and thickness of each component shown in the drawings may be arbitrarily shown for convenience of description, embodiments of the present disclosure are not necessarily limited to the illustrated components.

Hereinafter, embodiments of the present disclosure will be described in detail with reference to the accompanying drawings, and in description with reference to the drawings, the same or corresponding components are given the same reference numerals, and redundant description thereto will be omitted.

The present disclosure concerns a foldable display device having a support layer that includes a pattern portion overlapping with a folding area that is foldable along a folding axis. The pattern portion may have an auxetic structure and has a negative Poisson's ratio. The pattern portion includes a plurality of areas arranged in a direction perpendicular to the folding axis. The plurality of areas of the pattern portion may have respective moduli that increases in a direction from the folding axis towards the outside of the folding area. The support layer having the pattern portion may provide the foldable display device with increased flexibility and impact resistance as well as reduced manufacturing costs.

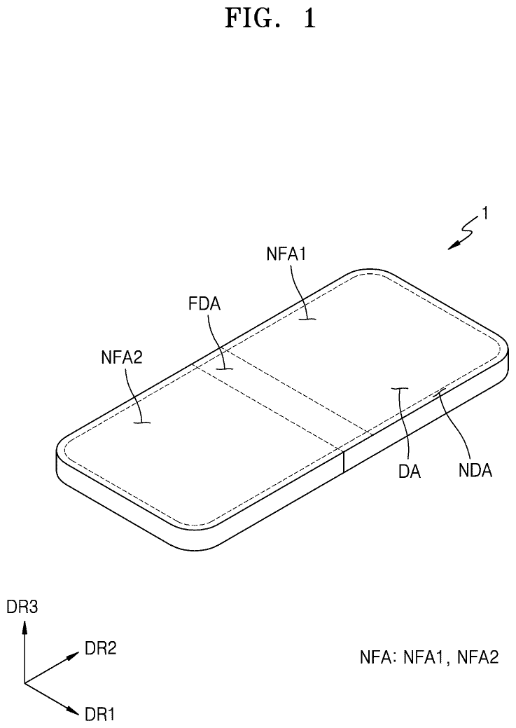

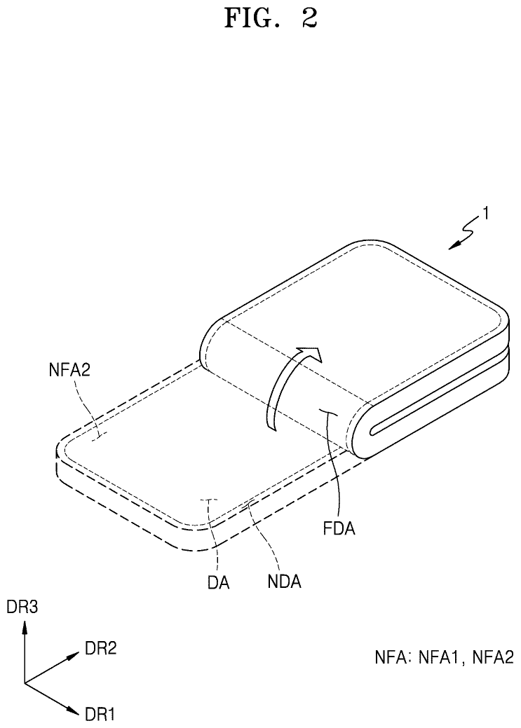

FIG. 1 is a perspective view showing an unfolded state of a foldable display device 1 according to an embodiment of the present disclosure, and FIG. 2 is a perspective view showing a folded state of the foldable display device 1 according to an embodiment of the present disclosure.

Referring to FIGS. 1 and 2, the foldable display device 1 according to an embodiment of the present disclosure may display a screen or an image through a display area DA, and various devices including the display area DA may be included therein. For example, the foldable display device 1 according to embodiments of the present disclosure may be applied to various home appliances such as not only smartphones, but mobile phones, tablet personal computers (PCs), personal digital assistant (PDAs), portable multimedia players (PMPs), televisions, game consoles, wristwatch-type electronic devices, head-mounted displays, monitors for PCs, laptop computers, vehicle navigation systems, vehicle dashboards, digital cameras, camcorders, outdoor billboards, electronic display boards, medical devices, inspection devices, refrigerators, washing machines, and the like, or the Internet of things (IoT) devices. However, embodiments of the present disclosure are not necessarily limited thereto and the electronic device that the foldable display device 1 may be applied to may be various different small-sized, medium-sized or large-sized electronic devices.

In an embodiment, the foldable display device 1 may be a light-emitting display device such as an organic light-emitting display device using an organic light-emitting diode, a quantum dot light-emitting display device including a quantum dot light-emitting layer, an inorganic light-emitting display device including an inorganic semiconductor, and a micro light-emitting display device using a micro light-emitting diode (LED). Hereinbelow, the foldable display device 1 is described mainly as an organic light-emitting display device, but embodiments of the present disclosure are not necessarily limited thereto. For example, in some embodiments, as the foldable display device 1, other types of display devices such as a liquid crystal display (LCD), a quantum dot liquid crystal display (QD), a quantum nano light-emitting display panel (nano NED), and a micro LED may be applied.

The foldable display device 1 may include a display area DA and a non-display area NDA. The display area DA may display at least one moving and/or static image. The display area DA may include a plurality of pixels. The plurality of pixels may be arranged in a matrix direction. The non-display area NDA may not display an image and may not include pixels. In an embodiment in which the foldable display device 1 has a touch function, the foldable display device 1 may include a touch area where touch input is detected, and the touch area may overlap with the display area DA. Although embodiments of the present disclosure are not necessarily limited thereto, the touch area may be substantially identical to the display area DA.

The shape of the display area DA may correspond to the shape of the foldable display device 1 to which the display area DA is applied. In an embodiment, the display area DA may be a rectangle with vertical edges on a plane or a rectangle with rounded edges. However, the planar shape of the display area DA is not necessarily limited to the rectangle illustrated in the drawing, and may have a circular, oval, or other various shapes.

The drawing illustrates an example in which a short side of the rectangle of the display area DA extends in a first direction DR1 and a long side thereof extends in a second direction DR2 perpendicular to the first direction DR1. A third direction DR3 may be perpendicular to the first direction DR1 and the second direction DR2, respectively, and may refer to a thickness direction of the foldable display device 1. However, it should be understood that the directions mentioned in an embodiment refer to relative directions, and embodiments of the present disclosure are not necessarily limited to the mentioned directions.

The non-display area NDA may surround the display area DA (e.g., in a plan view). For example, in an embodiment the non-display area NDA may surround all sides of the display area DA. However, embodiments of the present disclosure are not necessarily limited thereto, and the non-display area NDA may not be positioned near at least some of the four sides of the display area DA. A bezel area of the foldable display device 1 may be configured as the non-display area NDA.

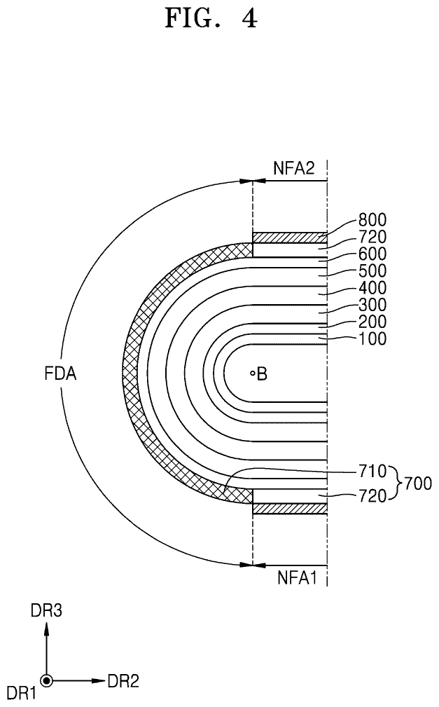

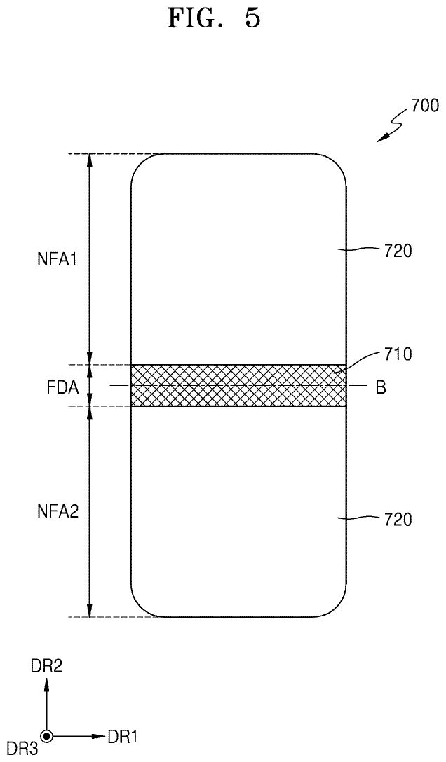

The foldable display device 1 is a foldable display device that may be freely bent or unfolded within a predetermined range. The foldable display device 1 may be folded based on a folding axis B (see FIGS. 4 and 5), and may be state-switched between a folding state (e.g., a folded state) and a non-folding state (e.g., an unfolded state). The folding state may be referred to as a state where the foldable display device 1 is bent out of the non-folding state even if it is not completely folded.

The foldable display device 1 may include a folding area FDA and a non-folding area NFA arranged around (e.g., adjacent to) at least one side of the folding area FDA (e.g., in the second direction DR2 and a direction opposite to the second direction DR2). The folding area FDA may be a portion that is bent within the foldable display device 1, and the non-folding area NFA may be a portion that is not bent within the foldable display device 1. The foldable display device 1 may be folded as the folding area FDA is bent. The foldable display device 1 may include a plurality of folding areas FDA.

In an embodiment, folding may include in-folding in which a display surface of the foldable display device 1 is folded inwardly to face itself and out-folding in which the display surface is folded outwardly. FIG. 2 shows an in-folded state of the foldable display device 1, but embodiments of the present disclosure are not necessarily limited thereto, and the foldable display device 1 may also be folded in an out-folding manner.

In addition, in an embodiment the foldable display device 1 may be folded in any one manner of in-folding and out-folding, or both in-folding and out-folding may be performed. In an embodiment of a display device in which both in-folding and out-folding are made, in-folding and out-folding may be performed based on the same folding area FDA, or may include a plurality of folding areas, such as an in-folding-only folding area and an out-folding-only folding area, in which different types of folding are performed. In the present specification, “foldable” should be interpreted to include partial folding, full folding, rollable, in-folding, out-folding, deformable and flexible.

In an embodiment, the folding area FDA may extend in a direction parallel to one side of the foldable display device 1. For example, the folding area FDA may extend in a direction (e.g., the first direction DR1) in which the short side of the foldable display device 1 extends. In the foldable display device 1 having a rectangular shape in which a side extending in the second direction DR2 is longer than a side extending in the first direction DR1, illustrated in the drawing, when the foldable display device 1 has the folding area FDA extending in the first direction DR1, a long side (e.g., a side extending in the second direction DR2) of the foldable display device 1 may be reduced to a half or less before and after folding, but the short side (e.g., the side extending in the first direction DR1) may be maintained. In an embodiment, the folding area FDA may extend in the same direction (e.g., the second direction DR2) as an extending direction of the long side (e.g., the side extending in the second direction DR2).

The folding area FDA may also have a predetermined width in the second direction DR2. In an embodiment, the width of the folding area FDA in the second direction DR2 may be much less than the width in the first direction DR1. The area of the folding area FDA may not be fixed and may be determined according to a radius of curvature.

The non-folding area NFA may include a first non-folding area NFA1 located on one side of the folding area FDA in the second direction DR2 and a second non-folding area NFA2 located on the other side of the folding area FDA in the second direction DR2. The widths of the first non-folding area NFA1 and the second non-folding area NFA2 in the second direction DR2 may be the same as each other, but are not necessarily limited thereto, and the widths of the first non-folding area NFA1 and the second non-folding area NFA2 in second direction DR2 may be different from each other depending on the position of the folding area FDA.

In an embodiment, the display area DA may be positioned across both the first non-folding area NFA1 and the second non-folding area NFA2. Furthermore, the display area DA may also be located in the folding area FDA corresponding to a boundary between the first non-folding area NFA1 and the second non-folding area NFA2. For example, the display area DA of the foldable display device 1 may be arranged continuously regardless of a boundary between the non-folding area (NFA) and the folding area (FDA), etc. However, in an embodiment, without being necessarily limited thereto, the display area DA may be located in only one of the first non-folding area NFA1 and the second non-folding area NFA2, or the display area DA may be arranged in the first non-folding area NFA1 and the second non-folding area NFA2, but the display area DA may not be arranged in the folding area FDA.

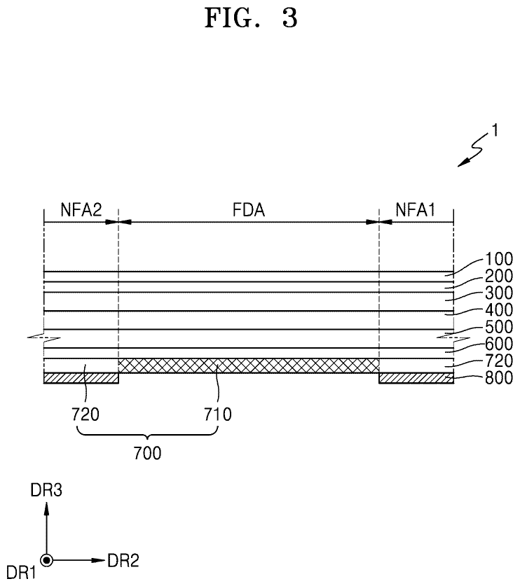

FIG. 3 is a cross-sectional view of a non-folding state of the foldable display device 1 according to an embodiment of the present disclosure, and FIG. 4 is a cross-sectional view of an in-folding state of the foldable display device 1 according to an embodiment of the present disclosure.

Referring to FIGS. 3 and 4, in an embodiment the foldable display device 1 may include a protective layer 100, a cover window 200, a shock absorbing layer 300, an anti-reflection member 400, a display panel 500, a polymer film layer 600, a support layer 700, and a heat dissipation member 800 that are sequentially stacked in the thickness direction (e.g., the third direction DR3). In an embodiment, at least one bonding member, such as an adhesive layer or a sticky layer, may be arranged between stacked members to bond adjacent stacked members to each other.

The protective layer 100 may serve to protect the lower cover window 200. In addition, the protective layer 100 may perform at least one of functions of preventing scattering, absorbing shock, preventing scratches, preventing fingerprints, and preventing glare of the cover window 200.

The protective layer 100 may include a transparent polymer film. For example, in an embodiment the protective layer 100 may include at least one selected from a group including polyethylene terephthalate (PET), polyethylene naphthalate (PEN), polycarbonate (PC), polymethyl methacrylate (PMMA), polystyrene, polyvinylchloride, polyethersulfone (PES), polyethylene, and polypropylene (PP), or at least one selected from a group including combinations thereof.

The cover window 200 may be disposed under the protective layer 100 (e.g., in a direction opposite to the third direction DR3). The cover window 200 may serve to cover and protect the lower stacked members. The cover window 200 may include a transparent material. For example, the cover window 200 may include glass or plastic.

In an embodiment in which the cover window 200 includes plastic, the plastic may be, for example, but not necessarily limited to, polyimide. In an embodiment in which the cover window 200 includes glass, the glass may be, for example, ultra-thin glass (UTG) or thin film glass. The cover window 200 may have flexible characteristics and thus may be bent, folded, or rolled.

The shock absorbing layer 300 may be disposed under the cover window 200 (e.g., in a direction opposite to the third direction DR3). The shock absorbing layer 300 may increase the durability of the cover window 200 and increase optical performance. The shock absorbing layer 300 may be optically transparent. However, embodiments of the present disclosure are not necessarily limited thereto. For example, in an embodiment the shock absorbing layer 300 may be omitted.

The anti-reflection member 400 may be disposed under the shock absorbing layer 300 (e.g., in a direction opposite to the third direction DR3). The anti-reflection member 400 may serve to reduce external light reflection. For example, in an embodiment the anti-reflection member 400 may be a polarizing film. In this embodiment, the anti-reflection member 400 may polarize light passing therethrough. However, the anti-reflection member 400 is not necessarily limited thereto. For example, in an embodiment, the anti-reflection member 400 may be a color filter layer within the display panel 500.

The display panel 500 may be disposed under the anti-reflection member 400 (e.g., in a direction opposite to the third direction DR3). The display panel 500 may display a screen or an image. In an embodiment, the display panel 500 may include a flexible board including flexible plastic, etc., instead of a rigid board including rigid glass, etc. Accordingly, the display panel 500 may be freely bent or unfolded within a predetermined range.

The display panel 500 may include at least one thin film transistor (TFT) and a light-emitting element electrically connected to the at least one thin film transistor to emit light. In an embodiment, the display panel 500 may include an organic light-emitting display panel, but is not necessarily limited thereto. For example, in some embodiments other display panels listed above or known in the art may also be applied for the display panel 500.

The polymer film layer 600 may be disposed under the display panel 500 (e.g., in a direction opposite to the third direction DR3). For example, in an embodiment the polymer film layer 600 may include polyimide (PI), polyethylene terephthalate (PET), polycarbonate (PC), polyethylene (PE), polypropylene (PP), polysulfone (PSF), polymethyl methacrylate (PMMA), triacetyl cellulose (TAC), cycloolefin polymer (COP), etc.

The polymer film layer 600 may include a functional layer on at least one surface. The functional layer may include, for example, a light-absorbing layer. The light-absorbing layer may include a light-absorbing material such as a black pigment, dye, etc. The light-absorbing layer may be formed on a polymer film using a black ink by coating or printing.

In an embodiment, the support layer 700 may be disposed under the polymer film layer 600 (e.g., in a direction opposite to the third direction DR3). The support layer 700 may increase the durability of the foldable display device 1 against impact that may be applied in the thickness direction (e.g., the third direction DR3) and may reduce a drop impact when the foldable display device 1 is dropped. In addition, the support layer 700 may reduce stress against a mechanical strain such as repeated folding of the foldable display device 1, and may provide elasticity to allow the foldable display device 1 to be unfolded without creases when unfolded after folded. Furthermore, the support layer 700 may support the display panel 500, release or disperse heat generated from the display panel 500, and prevent foreign substances from entering the display panel 500 from the outside (e.g., the external environment).

In an embodiment, the support layer 700 may include at least one material selected from stainless steel (SUS), copper (Cu), and graphite. In an embodiment in which the support layer 700 includes stainless steel, the durability of the support layer 700 may be increased. Additionally, in an embodiment in which the support layer 700 includes copper or graphite, the heat dissipation characteristics of the support layer 700 may be increased. In an embodiment, the thickness of the support layer 700 in the third direction DR3 may have a value in a range of about 50 μm to about 100 μm.

In an embodiment, the support layer 700 may include a pattern portion 710 positioned in the folding area FDA and a non-pattern portion 720 positioned in the non-folding area NFA. A detailed description thereof will be provided later.

The heat dissipation member 800 may be disposed under the support layer 700 (e.g., in a direction opposite to the third direction DR3). The heat dissipation member 800 may serve to diffuse heat generated from the display panel 500 or other components of the foldable display device 1. The heat dissipation member 800 may include a metal plate. In an embodiment, the metal plate may include, for example, metal with excellent thermal conductivity, such as stainless steel, copper, silver, etc. The heat dissipation member 800 may include a heat dissipation sheet including graphite or carbon nanotubes.

To facilitate folding of the foldable display device 1, some layers of the foldable display device 1 may be separated from themselves based on the folding area FDA. For example, the heat dissipation member 800 constituting the lowermost layer of the foldable display device 1 and having low ductility may be separated based on the folding area FDA. In another example, the support layer 700 or the polymer film layer 600 may be separated from itself based on the folding area FDA, but when they have sufficient ductility, the layers may be connected as one piece regardless of the folding area FDA and the non-folding area NFA.

In an embodiment, a folding axis B of the foldable display device 1 may extend in the longitudinal direction (e.g., the first direction DR1) of the folding area FDA on the protective layer 100. In an embodiment, when the foldable display device 1 is folded based on the folding axis B, the second non-folding area NFA2 may overlap the first non-folding area NFA1 in the thickness direction (e.g., the third direction DR3), as shown in FIG. 4. At this time, the protective layer 100, the cover window 200, the shock absorbing layer 300, the anti-reflection member 400, the display panel 500, the polymer film layer 600, and the support layer 700 may be bent to form a cross-sectional curve in the width direction (e.g., the second direction DR2) of the folding area FDA.

The support layer 700 may need to secure a certain level of impact resistance (e.g., hardness) to protect the display panel 500, and need to secure a certain level of flexibility to be bent to form a cross-sectional curve in the folding area FDA. In this embodiment, the support layer 700 may secure both impact resistance in the entire area of the support layer 700 and bendability in the folding area FDA by including an auxetic structure formed in some area (e.g., the pattern portion 710). For a more detailed description thereof, FIGS. 5 to 8 will be referred to.

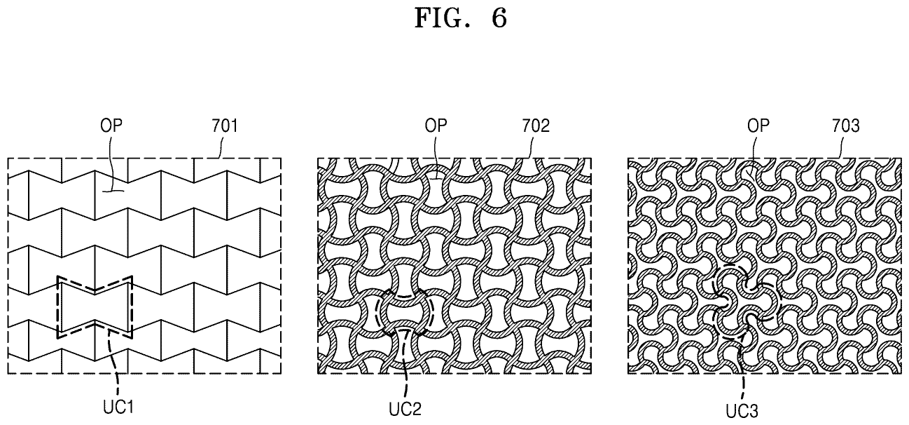

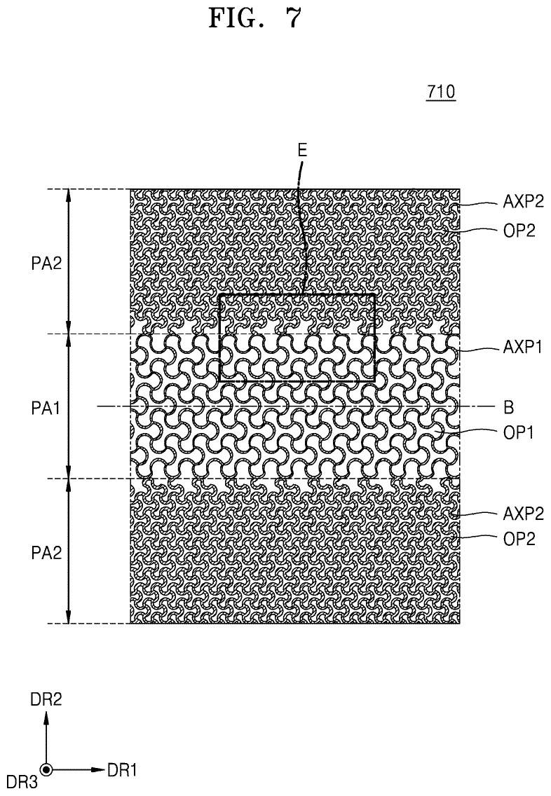

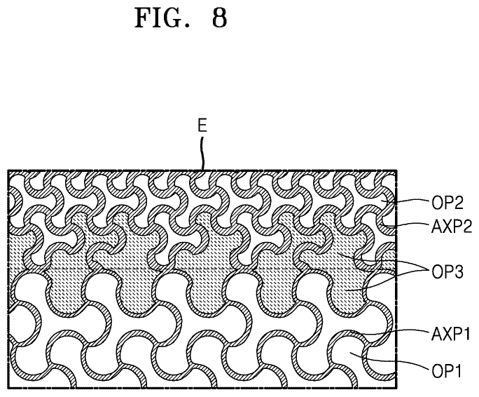

FIG. 5 is a plan view of the support layer 700 according to an embodiment of the present disclosure, and FIG. 6 is a view for describing a pattern formed in the pattern portion 710 of the support layer 700. FIG. 7 is a plan view of the pattern portion 710 according to an embodiment of the present disclosure, and FIG. 8 is an enlarged plan view of a portion E of FIG. 7.

Referring to FIGS. 5 to 8, the support layer 700 may include the pattern portion 710 and a non-pattern portion 720. In an embodiment, the non-pattern portion 720 may be positioned to overlap the non-folding area NFA of the foldable display device 1 (e.g., in the third direction DR3). For example, in an embodiment the non-pattern portion 720 may be provided as two pieces to respectively overlap the first non-folding area NFA1 and the second non-folding area NFA2. Patterns may not be formed in the non-pattern portion 720.

The non-pattern portion 720 may support the non-folding area NFA of the display panel 500. The polymer film layer 600 may be arranged on a surface of the display panel 500, and the non-pattern portion 720 may support the non-folding area NFA of the display panel 500 in a fixed state of being attached to the polymer film layer 600. In an embodiment, an adhesive layer may be provided between the non-pattern portion 720 and the polymer film layer 600. The adhesive layer may use resin, a pressure sensitive adhesive (PSA), etc., but the type of adhesive layer is not necessarily limited thereto and various types of adhesives may be utilized.

The pattern portion 710 may be disposed between the non-pattern portions 720. The pattern portion 710 may be positioned adjacent to (e.g., directly adjacent thereto) the folding axis B and may overlap the folding area FDA of the foldable display device 1 (e.g., in the third direction DR3).

The pattern portion 710 may include an auxetic structure having a negative Poisson's ratio. The Poisson's ratio may refer to a ratio of the amount of deformation of an object in a direction perpendicular to a tensile direction to the amount of deformation of the object in the tensile direction when a tensile stress is applied to the object. When the pattern portion 710 has a negative Poisson's ratio, the pattern portion 710 may expand without contracting in the first direction DR1 in application of the tensile stress to the pattern portion 710 in the second direction DR2.

The pattern portion 710 may include the auxetic structure having a Poisson ratio close to 0. When the foldable display device 1 is folded uniaxially, unidirectional stress mainly occurs. In this case, the auxetic structure having a small absolute value of the Poisson's ratio may be favorable to reduction of structural elasticity and stress under the unidirectional stress. Accordingly, the pattern portion 710 may reduce stress against a mechanical strain of the foldable display device 1 due to a folding operation by including an auxetic structure having a negative Poisson's ratio, but a small absolute value.

In the present specification, patterns forming an auxetic structure may be referred to as auxetic patterns. First, second, and third auxetic patterns 701, 702, and 703 of FIG. 6 illustrate auxetic patterns applied to the pattern portion 710. Referring to FIG. 6, in an embodiment the first to third auxetic patterns 701, 702, and 703 may respectively include first to third unit cells UC1, UC2, and UC3 defining openings OP. The shapes of the auxetic patterns shown in FIG. 6 are only examples, and the shapes of the patterns applied to the pattern portion 710 may not be necessarily limited thereto and may include various other shapes as long as they have a negative Poisson's ratio.

The first auxetic pattern 701 may include first lines extending in one direction and second lines extending in a different direction from the first line. In an embodiment, the second lines may be bent concavely. The first lines may be positioned between adjacent second lines, respectively.

Two adjacent first lines and two adjacent second lines may form one first unit cell UC1. In an embodiment, the first unit cell UC1 may have a ribbon-like shape on a plane. In an embodiment, the first unit cell UC1 may be connected to (e.g., directly connected thereto) six adjacent cells with interlocking lines. The Poisson's ratio of the first auxetic pattern 701 may be −0.8.

The second auxetic pattern 702 may include curves. In an embodiment, the second auxetic pattern 702 may include convex curves in opposite directions from the center of the opening OP and concave curves towards the center of the opening OP.

Two adjacent convex curves and two adjacent concave curves may form one second unit cell UC2. In an embodiment, the second unit cell UC2 may have a ribbon-like shape on a plane. In an embodiment, the second unit cell UC2 may be connected to (e.g., directly connected thereto) four adjacent cells with interlocking curves. In an embodiment, the cells connected to the second unit cell UC2 may correspond to a shape in which the second unit cell UC2 is rotated 90 degrees. The Poisson's ratio of the second auxetic pattern 702 may be −0.3.

The third auxetic pattern 703 may include curves. In an embodiment, the third auxetic pattern 703 may include convex curves in opposite directions from the center of the opening OP and concave curves towards the center of the opening OP.

Three adjacent convex curves and three adjacent concave curves may form one third unit cell UC3. The third unit cell UC3 may have a structure in which a concave curve is connected between every convex curves. In an embodiment, the third unit cell UC3 may be connected to six adjacent cells with interlocking curves. The Poisson's ratio of the third auxetic pattern 703 may be about −0.1.

In an embodiment, as shown in FIG. 7, the pattern portion 710 may include a plurality of areas in which different patterns are formed. In an embodiment, the pattern portion 710 may include a first area PA1 and two second areas PA2 positioned on either side of the first area PA1 (e.g., in the second direction DR2).

The first area PA1 may be arranged adjacent to (e.g., directly adjacent thereto) the folding axis B in the pattern portion 710 that overlaps the folding area FDA and may extend longitudinally in a direction parallel to the folding axis B. The second area PA2 may be arranged on at least one side of the first area PA1 with respect to the second direction DR2 and may extend longitudinally in a direction parallel to the folding axis B. For example, in an embodiment the pattern portion 710 may have the first area PA1 disposed in a center portion in the second direction DR2, and the second area PA2 disposed in each of opposite outer portions in the second direction DR2.

The width of the first area PA1 in the second direction DR2 may correspond to (e.g., be equal to) the width of the second area PA2 in the second direction DR2. For example, in an embodiment a ratio of the widths of a 2nd-1 area PA2, the first area PA1, and a 2nd-2 area PA2, which are sequentially arranged in the second direction DR2, may be approximately about 1:1:1. However, embodiments of the present disclosure are not necessarily limited thereto, and the widths of the first area PA1 and the second area PA2 in the second direction DR2 may be changed according to the folding design of the foldable display device 1.

Each of the first area PA1 and the second area PA2 may have a predetermined modulus. The modulus of each of the first area PA1 and the second area PA2 may be defined as an average modulus of each area. The modulus may be proportional to a stiffness of a material. When the modulus is small, a strain is greater when the same stress is applied than when the modulus is large, and an elastic range that may exhibit elasticity and a restoring force may be larger.

A first modulus of the first area PA1 may be less than a second modulus of the second area PA2. For example, in an embodiment the first modulus of the first area PA1 may have a value within a range of about 10 MPa to about 300 MPa, and the second modulus of the second area PA2 may have a value within a range of about 300 MPa to about 1 GPa. Accordingly, the first area PA1 may have greater resilience and flexibility than the second area PA2, and the second area PA2 may have greater impact resistance (e.g., hardness) than the first area PA1.

When the foldable display device 1 is folded, a greater tensile stress may be applied in a direction from the folding area FDA towards the folding axis B. Thus, the pattern portion 710 of the foldable display device 1 according to an embodiment of the present disclosure may divide an area in the second direction DR2 that is perpendicular to the folding axis B, and include the first area PA1 having a relatively small first modulus adjacent to (e.g., immediately adjacent thereto) the folding axis B and include the second area PA2 having a relatively large second modulus on either side of the first area PA1 (e.g., in the second direction DR2), thereby simultaneously increasing the flexibility and impact resistance of the foldable display device 1.

Each of the first area PA1 and the second area PA2 may include an auxetic pattern having a negative Poisson's ratio. The first area PA1 may include a first pattern AXP1, and the second area PA2 may include a second pattern AXP2. At this time, each of the first pattern AXP1 and the second pattern AXP2 may be an auxetic pattern having a Poisson's ratio substantially close to 0. In an embodiment as shown in FIG. 7, the first pattern AXP1 and the second pattern AXP2 may be directly connected to each other.

For example, in an embodiment the Poisson's ratios of the first pattern AXP1 and the second pattern AXP2 may be at least about −0.3, and specifically at least about −0.1. The closer the Poisson's ratios of the first area PA1 and the second area PA2 are to 0, the smaller the degree of shape deformation when tensile force is applied to the pattern portion 710. Accordingly, by including the first pattern AXP1 and the second pattern AXP2 having a negative Poisson's ratio close to 0 in the pattern portion 710, the support layer 700 may have a predetermined flexibility while simultaneously preventing the surface quality of the foldable display device 1 from being degraded.

In an embodiment, the first pattern AXP1 and the second pattern AXP2 may have the same shape as the third auxetic pattern 703 shown in FIG. 6, but are not necessarily limited thereto, and various auxetic patterns having a negative Poisson's ratio may be used for the first pattern AXP1 and the second pattern AXP2. Hereinafter, for convenience of description, the present disclosure will be described focusing on an embodiment in which the first pattern AXP1 and the second pattern AXP2 have the same shape (e.g., in a plan view) as the third auxetic pattern 703 shown in FIG. 6.

In an embodiment, the first pattern AXP1 may include a plurality of closed curves. For example, the first pattern AXP1 may be a shape in which closed curves of the same shape are repeated. Repeated unit closed curves may form a unit cell. A first opening OP1 may be defined inside a unit cell of the first pattern AXP1.

In an embodiment, the second pattern AXP2 may include a unit cell having the same shape as the first pattern AXP1. For example, the second pattern AXP2 may be a shape in which closed curves of the same shape are repeated, and the repeated unit closed curves may form a unit cell of the same shape as the unit cell of the first pattern AXP1. A second opening OP2 may be defined inside the unit cell of the second pattern AXP2.

The line widths (e.g., line thicknesses) of the first pattern AXP1 and the second pattern AXP2 may be in a range of about 5 μm to about 150 μm. In an embodiment, the line width of the first pattern AXP1 and the line width of the second pattern AXP2 may be different from each other. For example, in an embodiment the line width of the first pattern AXP1 may be less than the line width of the second pattern AXP2. For example, the first pattern AXP1 may include thinner curves than the second pattern AXP2.

In an embodiment, the first pattern AXP1 and the second pattern AXP2 may have different pitches at which unit cells are repeatedly arranged. Herein, the pitch may be defined as a distance between the centers of two adjacent unit cells. In an embodiment, the pitch at which unit cells are repeatedly arranged in the first pattern AXP1 may be greater than the pitch of the second pattern AXP2. For example, the distance between the centers of the unit cells of the first pattern AXP1 may be greater than that of the second pattern AXP2. In this embodiment, the unit cell of the first pattern AXP1 may have a larger size (e.g., area in a plan view) than the unit cell of the second pattern AXP2.

In an embodiment in which the first pattern AXP1 and the second pattern AXP2 differ only in line width, the second pattern AXP2 with the greater line width may have the greater stiffness. In an embodiment in which the first pattern AXP1 and the second pattern AXP2 differ only in pitch, the second pattern AXP2 with the smaller pitch may have the greater stiffness.

The pattern portion 710 according to an embodiment of the present disclosure may form the first pattern AXP1 and the second pattern AXP2 using an auxetic structure of the same shape, and by changing the line width and/or pitch between the first pattern AXP1 and the second pattern AXP2, the first pattern AXP1 and the second pattern AXP2 may have different moduli from each other. For example, in an embodiment in which the first pattern AXP1 has a smaller line width and greater pitch than those of the second pattern AXP2, the first pattern AXP1 may have a smaller modulus than that of the second pattern AXP2. The second pattern AXP2, which has greater line width and smaller pitch than those of the first pattern AXP1, may have a greater modulus than that of the first pattern AXP1.

As shown in FIG. 8, the first pattern AXP1 and the second pattern AXP2 may be connected to each other at a boundary between the first area PA1 and the second area PA2. For example, in an embodiment, at the boundary between the first area PA1 and the second area PA2, the curves of the first pattern AXP1 and the curves of the second pattern AXP2 may be connected to one another irregularly or regularly, and a third opening OP3 may be formed between the first pattern AXP1 and the second pattern AXP2. In an embodiment shown in FIG. 8, the third openings OP3 formed by connecting the first pattern AXP1 and the second pattern AXP2 are irregularly formed. However, embodiments of the present disclosure are not necessarily limited thereto, and the third openings OP3 may be formed in a regular shape depending on the line widths and pitches, and curve lengths of connecting portions of the first pattern AXP1 and the second pattern AXP2.

In an embodiment, the first pattern AXP1 and the second pattern AXP2 may include a non-magnetic material that does not respond to (e.g., is non-reactive thereto) a magnetic field. In an embodiment in which the first pattern AXP1 and the second pattern AXP2 include a non-magnetic material, the foldable display device 1 may not disturb an operation of recognizing a user's input using a magnetic field. For example, the first pattern AXP1 and the second pattern AXP2 may include, but are not necessarily limited to, stainless steel, copper, aluminum, or high-density polyethylene (HDPE).

In an embodiment, the pattern portion 710 may further include a filling member that fills openings of the first pattern AXP1 and the second pattern AXP2. The filling member may include a high-elasticity material. For example, in an embodiment, the filling member may include a polymeric resin, such as rubber, an elastomer, or the like.

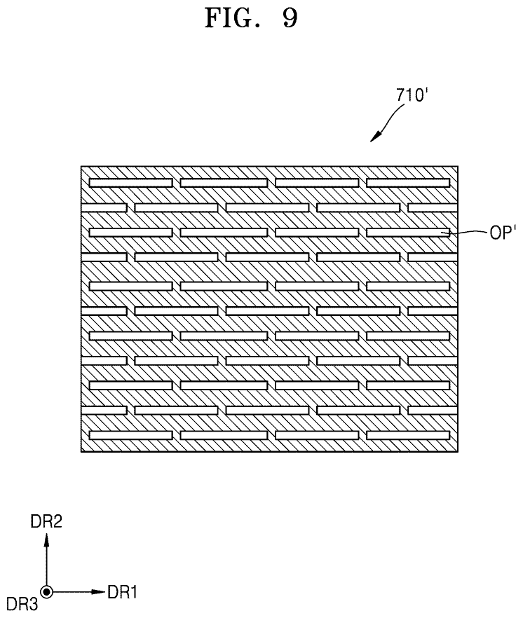

FIG. 9 is a plan view showing a pattern portion 710′ of a foldable display device according to a comparative example.

Referring to FIG. 9, the pattern portion 710′ of the support layer according to the comparative example may include openings OP′ having a rectangular shape and may have a positive Poisson's ratio. Accordingly, when stress is applied to the pattern portion 710′ of the support layer according to the comparative example in the second direction DR2, the pattern portion 710′ may contract in the first direction DR1 and deformation occurs in the shape of the opening OP′.

In a comparative in embodiment in which the support layer including such a pattern portion 710′ is attached to a polymer film layer 600 on a display panel 500 using a single adhesive layer, the pattern portion 710′ may be fixed to the polymer film layer 600 in a deformed state, and such deformation may be visible to outside (e.g., the external environment). For example, the surface quality of the foldable display device 1 may be degraded. To prevent such a problem, the support layer according to the comparative example need to have the adhesive layer disposed only on the non-folding area NFA and the adhesive layer removed from the pattern portion 710′ thereof, which may again cause reduction of the impact resistance of the foldable display device 1.

In contrast, as the pattern portion 710 according to an embodiment of the present disclosure has a negative Poisson's ratio close to 0, flexibility may be secured while minimizing deformation in the first direction DR1. The support layer 700 including the pattern portion 710 may be attached to (e.g., coupled to) the polymer film layer 600 using an adhesive layer that covers both the pattern portion 710 and the non-pattern portion 720, thereby simplifying the manufacturing process of the foldable display device 1 and increasing the impact resistance of the foldable display device 1. In addition, unlike the pattern portion 710′ according to the comparative example, the pattern portion 710 according to an embodiment of the present disclosure may have the first opening OP1 and the second opening OP2 formed relatively densely, and when stress is applied to the pattern portion 710, deformation of the first opening OP1 and the second opening OP2 may occur to a minimum, such that patterns of the pattern portion 710 may not be visible to the outside (e.g., the external environment), and the surface quality of the foldable display device 1 may be secured.

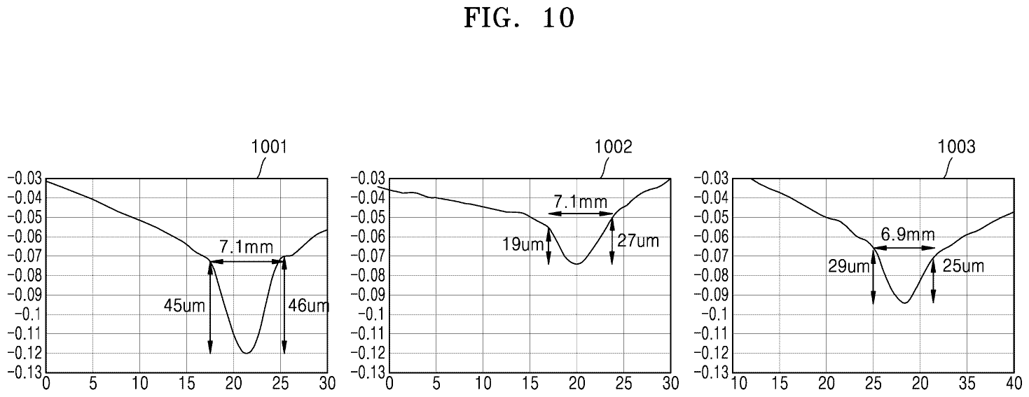

FIG. 10 is a graph showing bending occurring in foldable display devices according to a first comparative example and a second comparative example and a foldable display device according to an embodiment of the present disclosure.

Referring to FIG. 10, a folding test is performed using foldable display devices according to the first comparative example and the second comparative example and a test foldable display device manufactured as the foldable display device according to an embodiment of the present disclosure, and results are presented in a graph. In the folding test, when the foldable display device is folded at a curvature of about 1.4 at about 60 degrees for about 2 hours and then unfolded, the width and height of a crease that appears on the surface thereof are measured to identify the deformation degree of the foldable display device.

A graph 1001 shows a result of the folding test conducted using the foldable display device according to the first comparative example. The foldable display device according to the first comparative example may correspond to a case in which the pattern portion is formed as shown in FIG. 9, and the pattern portion according to the first comparative example may include one identical pattern as a whole and rectangular openings, and have a positive Poisson's ratio.

A graph 1002 shows a result of the folding test conducted using the foldable display device according to the second comparative example. The foldable display device according to the second comparative example may correspond to a case where the pattern portion is formed like the third auxetic pattern 703 of FIG. 6, and the pattern portion according to the second comparative example may include one identical pattern as a whole and have a negative Poisson's ratio.

A graph 1003 shows a result of the folding test conducted using the test foldable display device. The test foldable display device may correspond to a case where the pattern portion is formed as shown in FIG. 7, and the pattern portion may be divided into the first area PA1 and the second area PA2 having different moduli from each other, and the first pattern AXP1 and the second pattern AXP2 are formed in the first area PA1 and the second area PA2, respectively.

When comparing the graph 1003 with the graph 1001 and the graph 1002, it may be seen that the test foldable display device have a crease height of 27 μm and a crease width of 6.5 mm, such that both are reduced compared to the first comparative example (about 46 μm, about 7.1 mm), the crease width is reduced compared to the second comparative example (about 23 μm, about 7.1 mm), and there is no significant difference in crease height. Accordingly, it may be seen that the foldable display device 1 according to an embodiment of the present disclosure has an increased surface quality.

Table 1 provided below shows results of a pen drop test conducted using the foldable display devices according to the first comparative example and the second comparative example and the test foldable display device according to an embodiment of the present disclosure.

TABLE 1

| Foldable Display Device | Drop Height (cm) |
|---|---|
| First Comparative Example | 7 |
| Second Comparative Example | 10 |
| Test Foldable Display Device | 11 |

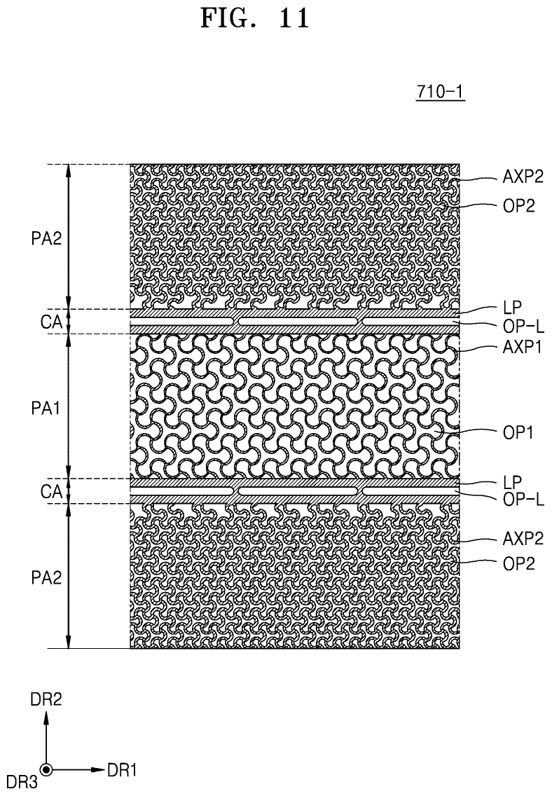

Referring to Table 1, it may be seen that the test foldable display device has an increased drop height compared to the first and second comparative examples. Accordingly, it may be seen that the foldable display device 1 according to an embodiment of the present disclosure has an increased impact resistance. FIG. 11 is a plan view of a pattern portion 710-1 of a support layer according to another embodiment of the present disclosure.

Referring to FIG. 11, the pattern portion 710-1 according to an embodiment of the present disclosure differs from the embodiment of FIG. 7 in that it further includes an intermediate area CA positioned between the first area PA1 and the second area PA2 (e.g., in the second direction DR2).

For example, in an embodiment the intermediate area CA may be arranged on either side of the first area PA1 (e.g., in the second direction DR2) and may extend longitudinally in the first direction DR1. The first area PA1 and the second area PA2 may be disconnected by the intermediate area CA. In this embodiment, the first pattern AXP1 of the first area PA1 and the second pattern AXP2 of the second area PA2 may not be directly connected to each other. In an embodiment, the width of the intermediate area CA in the second direction DR2 may be less than the width of the first area PA1 or the second area PA2 in the second direction DR2.

A lattice pattern LP having a positive Poisson's ratio may be formed in the intermediate area CA. The lattice pattern LP may include a plurality of openings OP-L extending longitudinally in the first direction DR1. As stress is applied to the pattern portion 710-1 in the second direction DR2, the opening OP-L may expand in the second direction DR2 and contract in the first direction DR1.

Accordingly, even the support layer having the pattern portion 710-1 may secure sufficient flexibility in the folding area FDA while ensuring impact resistance, and the efficiency of a process of forming the support layer may be increased. In addition, the foldable display device including the pattern portion 710-1 may further increase impact resistance due to the intermediate area CA.

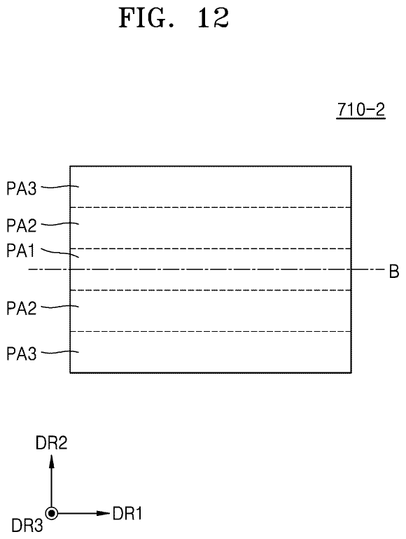

FIG. 12 is a plan view of a pattern portion 710-2 of a support layer according to an embodiment of the present disclosure.

Referring to FIG. 12, the pattern portion 710-2 according to an embodiment of the present disclosure differs from an embodiment of FIG. 7 in that it further includes a third area PA3 positioned adjacent to the second area PA2 (e.g., in the second direction DR2).

For example, in an embodiment the third area PA3 may be disposed outside the second area PA2, may be directly adjacent to the second area PA2 in the second direction DR2 and may extend longitudinally in the first direction DR1. For example, the third area PA3 may be the outermost area of the pattern portion 710-2 in the second direction DR2.

The third area PA3 may have a third modulus. In an embodiment, the first modulus of the first area PA1, the second modulus of the second area PA2, and the third modulus of the third area PA3 may respectively have gradually changing magnitudes.

For example, in an embodiment the modulus of the third area PA3 may have a greater value than the modulus of the second area PA2. In this embodiment, the first area PA1, the second area PA2, and the third area PA3 arranged consecutively in the second direction DR2 from the center of the pattern portion 710-2 may have gradually greater moduli in that order. For example, the modulus of the pattern portion 710-2 may decrease towards the center.

In an embodiment, the third area PA3 may include a third pattern, which is an auxetic pattern having a negative Poisson's ratio. In an embodiment, the third pattern AXP2 may include a unit cell having the same shape as the first pattern AXP1 and the second pattern AXP2. In an embodiment, the third pattern may also have a greater line width than the first pattern AXP1 and the second pattern AXP2, and may have a smaller pitch than the first pattern AXP1 and the second pattern AXP2.

In an embodiment, the pattern portion 710-2 may include the first area PA1, the second area PA2, and the third area PA3 having gradually changing moduli, thereby ensuring impact resistance while ensuring sufficient flexibility in the folding area FDA. In addition, the foldable display device including the pattern portion 710-2 may further increase impact resistance and surface quality by further including the third area PA3.

In addition, in some embodiments, the pattern portion may have four or more areas which have gradually changing moduli in which the moduli increases from the center towards the outside of the pattern portion. For example, the pattern portion according to an embodiment of the present disclosure may further include one or more areas in which the modulus increases towards the outer edge of the third area PA3.

As described above, the foldable display device 1 according to an embodiment of the present disclosure may form the pattern portion 710 using an auxetic structure having a negative Poisson's ratio in the folding area FDA of the support layer 700, and include the pattern portion 710 having a plurality of areas with different moduli, thereby reducing deformation due to stress occurring during folding and increasing the surface quality of the foldable display device 1.

Furthermore, the foldable display device 1 according to an embodiment of the present disclosure increase the modulus in the second direction DR2 from the center of the pattern portion 710, thereby increasing the flexibility of the folding area FDA while increasing the impact resistance.

In addition, the foldable display device 1 according to an embodiment of the present disclosure may have a reduced thickness compared to a comparative embodiment in which the support layer 700 includes a single pattern, and reduce process costs.

### The Electronic Device

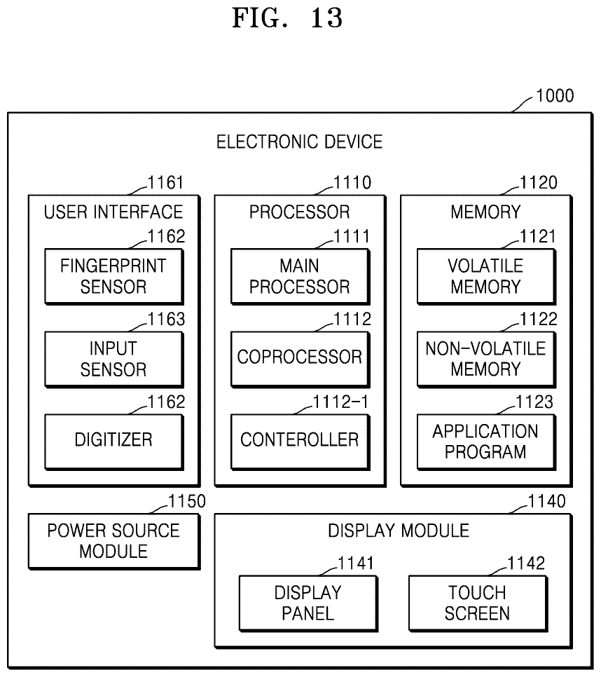

FIG. 13 is a diagram illustrating an electronic device according to an embodiment of the present invention. Referring to FIG. 13, the electronic device 1000 according to one embodiment of the present invention may output various information (e.g., images, text, music, etc.) through a display module 1140, which, for example, may correspond to the foldable display device 1 shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the foldable display device 1 shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

Each of the embodiments described above may be implemented independently, but it goes without saying that the structure of each embodiment may be applied in combination to other embodiments.

Although the present disclosure has been described with reference to an example shown in the drawings, it will be understood by those of ordinary skill in the art that various modifications and equivalent other examples may be made from the shown example. Accordingly, the true technical scope of the present disclosure should be defined by the technical spirit of the appended claims.

Specific implementations described in the embodiments are examples and do not limit the scope of the embodiments in any way. In addition, when there is no specific mentioning, such as “essential” or “important”, it may not be a necessary component for the application of the present disclosure.

In the specification (especially, claims) of the present disclosure, the use of the term “the” and similar indicators thereof may correspond to both the singular and the plural. Moreover, when a range is described in an example, the invention includes the application of individual values within the range (unless there is a statement to the contrary), and is the same as describing each individual value constituting the range in the detailed description. Finally, when there is no apparent description of the order of operations constituting the method according to the present disclosure or a contrary description thereof, the operations may be performed in an appropriate order. However, the embodiments are not necessarily limited according to the describing order of the operations. The use of all examples or exemplary terms in the present disclosure are to simply describe the present disclosure in detail, and unless the range of the present disclosure is not limited by the examples or the exemplary terms unless limited by the claims. In addition, it may be understood by those of ordinary skill in the art that various modifications, combinations, and changes may be made according to design conditions and factors within the scope of the appended claims or equivalents thereof.

A foldable display device according to embodiments of the present disclosure may prevent deformation due to tensile stress and improve surface quality by including a support layer disposed on a display panel including a first region and a second region that have different moduli.

Moreover, the foldable display device according to embodiments of the present disclosure may improve both flexibility and impact resistance by including a support layer having a modulus decreasing toward the center of the folding area.

However, the effects of the present disclosure are not limited to the foregoing effects, and may be expanded in various ways without departing from the spirit and scope of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more non-limiting embodiments have been described with reference to the figures, it will be understood by those of ordinary skill in the art that various changes in form and details may be made therein without departing from the spirit and scope of the present disclosure.

What is claimed is:

1. A foldable display device comprising:
a display panel comprising a folding area and a non-folding area adjacent to at least one side of the folding area; and
a support layer disposed on the display panel, the support layer comprising a pattern portion overlapping the folding area,
wherein the pattern portion comprises a first area having a first modulus, and a second area disposed on at least one side of the first area and having a second modulus different from the first modulus.

2. The foldable display device of claim 1, wherein the first modulus is less than the second modulus.

3. The foldable display device of claim 1, wherein:
the first modulus is in a range of about 10 MPa to about 300 MPa; and
the second modulus is in a range of about 300 MPa to about 1 GPa.

4. The foldable display device of claim 1, wherein a width of the second area is equal to a width of the first area.

5. The foldable display device of claim 1, wherein each of the first area and the second area has a negative Poisson's ratio.

6. The foldable display device of claim 1, wherein:
the first area comprises a first pattern defining a plurality of first unit cells;
the second area comprises a second pattern defining a plurality of second unit cells; and
each of the plurality of first unit cells and the plurality of second unit cells have a same shape as each other in a plan view.

7. The foldable display device of claim 6, wherein the first pattern and the second pattern have different line widths from each other.

8. The foldable display device of claim 6, wherein each first unit cell of the plurality of first unit cells has a size greater than a size of each second unit cell of the plurality of second unit cells.

9. The foldable display device of claim 6, wherein the first pattern and the second pattern are connected to each other.

10. The foldable display device of claim 6, wherein:
the pattern portion further comprises an intermediate area disposed between the first area and the second area; and
the intermediate area has a positive Poisson's ratio.

11. The foldable display device of claim 6, wherein the first pattern or the second pattern comprises at least one material selected from stainless steel, copper, aluminum, and high-density polyethylene (HDPE).

12. The foldable display device of claim 6, wherein the pattern portion further comprises a filling member filling openings of the first pattern and the second pattern.

13. The foldable display device of claim 1, further comprising an adhesive layer disposed between the display panel and the support layer, the adhesive layer coupling the display panel to the pattern portion.

14. The foldable display device of claim 1, wherein the pattern portion further comprises a third area disposed adjacent to the second area and having a third modulus.

15. The foldable display device of claim 14, wherein the first modulus, the second modulus, and the third modulus have respective sizes that gradually change.

16. The foldable display device of claim 14, wherein a modulus of the pattern portion decreases towards a center of the pattern portion.

17. The foldable display device of claim 1, wherein a thickness of the support layer is in a range of about 50 μm to about 100 μm.

18. A foldable display device comprising:
a display panel; and
a support layer disposed on the display panel,
wherein the support layer comprises a first area disposed adjacent to a folding axis of the display panel and a second area arranged on at least one side of the first area, and
the first area and the second area have different patterns from each other.

19. The foldable display device of claim 18, wherein a first pattern of the first area has a line width that is different from a line width of a second pattern of the second area.

20. An electronic device comprising:
a foldable display device,
wherein the foldable display device comprises:
a display panel comprising a folding area and a non-folding area adjacent to at least one side of the folding area; and
a support layer disposed on the display panel, the support layer comprising a pattern portion overlapping the folding area,
wherein the pattern portion comprises a first area having a first modulus, and a second area disposed on at least one side of the first area and having a second modulus different from the first modulus.
